(19) United States
(12) Patent Application Publication
(10) Pub. No.: US 2012/0318567 A1
(43) Pub. Date: Dec. 20, 2012

(54) WIRING STRUCTURES

(76) Inventors: Jong-Hyun PARK, Seoul (KR); Jee-Yong KIM, Hwaseongsi (KR); Joon-Hee LEE, Seongnam-si (KR); Jai-Hyuk SONG, Seongnam-si (KR); Sang-Youn JO, Suwon-si (KR)

(21) Appl. No.: 13/495,216

(22) Filed: Jun. 13, 2012

(30) Foreign Application Priority Data
Jun. 16, 2011 (KR) 10-2011-0058283

(51) Int. Cl. H05K 1/11; H05K 1/02; H05K 1/09

(52) U.S. Cl. 174/257; 174/264; 174/258

(57) ABSTRACT

A wiring structure includes a first plug extending through a first insulating interlayer on a substrate, a first wiring extending through a second insulating interlayer on the first insulating interlayer and the first wiring is electrically connected to the first plug, a diffusion barrier layer pattern on the first wiring and on the second insulating interlayer, a portion of the second insulating interlayer being free of being covered by the diffusion barrier layer pattern, a second plug extending through the diffusion barrier layer pattern, the second plug is in contact with the first wiring, and a second wiring electrically connected to the second plug.

### CROSS-REFERENCE TO RELATED APPLICATION

Korean Patent Application No. 10-2011-0058283, filed on Jun. 16, 2011 in the Korean Intellectual Property Office (KIPO), and entitled: “Wiring Structures and Methods of Manufacturing the Same,” is incorporated by reference herein in its entirety.

### BACKGROUND

Gate structures of semiconductor devices may include insulation layers, e.g., insulation layers including silicon oxide layers. In the insulation layers, some outer-shell electrons of, e.g., silicon atoms, at an interface between the substrate and the insulation layers may not be bonded, so that a dangling bond may be generated. The dangling bond may trap electrons, e.g., so that a threshold voltage of a transistor including the silicon oxide layer may increase or data retention characteristics may be deteriorated. Further, an insulating interlayer may be formed using a process that may generate impurities, e.g., hydrogen bonds, therein. A bond strength of, e.g., the hydrogen bonds, may be weak, so that atoms, e.g., hydrogen atoms, may migrate to adjacent layers. For example, atoms may migrate to a gate insulation layer, which may deteriorate electrical characteristics of the semiconductor device.

### SUMMARY

Embodiments may be realized by providing a wiring structure that includes a first plug extending through a first insulating interlayer and the first insulating interlayer is on a substrate, a first wiring extending through a second insulating interlayer and the second insulating interlayer is on the first insulating interlayer, the first wiring is electrically connected to the first plug, a diffusion barrier layer pattern on the first wiring and on the second insulating interlayer and a portion of the second insulating interlayer is free of being covered by the diffusion barrier layer pattern, a second plug extending through the diffusion barrier layer pattern and the second plug is in contact with the first wiring, and a second wiring electrically connected to the second plug.

An etch stop layer may be between the first insulating interlayer and the second insulating interlayer. A third insulating interlayer may be between the diffusion barrier layer pattern and the second wiring. The second plug may extend through both the third insulating interlayer and the diffusion barrier layer pattern.

The first wiring may include at least one selected from copper, aluminum, tungsten, platinum, and gold. The diffusion barrier layer pattern may include at least one selected from a silicon nitride, a tantalum oxide, a titanium oxide, a tantalum nitride, and a titanium nitride. The first and second insulating interlayers may include at least selected from a borosilicate glass, a borophosphosilicate glass, an undoped silicate glass, a spin on glass, a flowable oxide, a tetraethyl orthosilicate, a plasma enhanced tetraethyl orthosilicate, a high density plasma oxide, and a high temperature oxide.

The wiring structure may include a dummy plug on the second insulating interlayer and a dummy wiring on the dummy plug. The dummy plug may extend through the diffusion barrier layer pattern. The dummy wiring may be electrically isolated from the second wiring.

Embodiments may also be realized by providing a method of manufacturing a wiring structure that includes providing a first insulating interlayer on a substrate, forming a first plug through the first insulating interlayer, forming a first wiring through a second insulating interlayer and the second insulating interlayer is formed on the first insulating interlayer, the first wiring is formed to be electrically connected to the first plug, forming a diffusion barrier layer pattern on the first wiring and the second insulating interlayer such that a portion of the second insulating interlayer is free of being covered by the diffusion barrier layer pattern, forming a second plug through the diffusion barrier layer pattern such that the second plug is in contact with the first wiring, and forming a second wiring electrically connected to the second plug.

Forming the diffusion barrier layer pattern may include forming a diffusion barrier layer on the first wiring and the second insulating interlayer, and etching a portion of the diffusion barrier layer on the second insulating interlayer such that the diffusion barrier layer pattern covers the first wiring and partially covers another portion of the second insulating interlayer.

Forming the first wiring may include forming an opening in the second insulating interlayer such that the opening exposes the first plug, forming a conductive layer on the second insulating interlayer to fill the opening, and planarizing upper portions of the conductive layer using a top surface of the second insulating interlayer as a planarization endpoint to form the first wiring contacting the first plug.

The method may include forming a third insulating interlayer on the diffusion barrier layer pattern. The second plug may be formed extending through the diffusion barrier layer pattern and the third insulating interlayer.

The method may include forming a dummy plug through the diffusion barrier layer pattern such that the dummy plug is on the second insulating interlayer, and forming a dummy wiring on the dummy plug. The dummy wiring may be electrically isolated from the second wiring. The diffusion barrier layer pattern may be formed using at least one selected from a silicon nitride, a tantalum oxide, a titanium oxide, a tantalum nitride, and a titanium nitride.

Embodiments may also be realized by providing a wiring structure that includes a first contact structure on a substrate and a diffusion barrier layer pattern between the first wiring and the second wiring. The first contact structure includes a first contact plug, a first wiring, a second contact plug, and a second wiring that are sequentially stacked on the substrate to be electrically connected to each other. The first wiring extends through an insulating interlayer. The diffusion barrier layer pattern covers the first wiring and includes a gap exposing a portion of the insulating interlayer.

The second wiring may overlap the first wiring and the gap in the diffusion barrier layer pattern. The wiring structure may include a second contact structure overlapping the gap in the diffusion barrier layer pattern. The second contact structure may include a dummy plug and a dummy wiring. The dummy plug may extend through the gap to be in contact with the insulating interlayer. The dummy plug and the dummy wiring may be electrically isolated from the first contact plug, the second contact plug, the first wiring, and the second wiring.

Embodiments may also be realized by providing a wiring structure that includes a second contact structure as well as a first contact structure. A dummy plug of the second contact structure may be disposed through a diffusion barrier layer on a second insulating interlayer, so that impurities, e.g., hydrogen atoms remaining in a first insulating interlayer and the second insulating interlayer may be easily outgassed through an interface of the second insulating interlayer and the dummy plug.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a wiring structure in accordance with exemplary embodiments;

FIGS. 2 to 6 illustrate cross-sectional views depicting stages in a method of manufacturing a wiring structure in accordance with exemplary embodiments;

FIG. 7 illustrates a cross-sectional view of a wiring structure in accordance with some exemplary embodiments;

FIGS. 8 to 12 illustrate cross-sectional views depicting stages in a method of manufacturing a wiring structure in accordance with some exemplary embodiments;

FIGS. 13 to 16 illustrate cross-sectional views depicting stages in a method of manufacturing a semiconductor device in accordance with exemplary embodiments; and

FIGS. 17 to 20 illustrate cross-sectional views depicting stages in a method of manufacturing a semiconductor device in accordance with some exemplary embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “connected to” or “coupled to” another element or layer, it can be directly connected or coupled to the other element or layer or intervening elements or layers may be present. In contrast, when an element is referred to as being “directly connected to” or “directly coupled to” another element or layer, there are no intervening elements or layers present. As used herein, the teen “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the embodiments.

Spatially relative terms, such as “under,” “below,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of exemplary embodiments (and intermediate structures). As such, variations from the shapes of the illustrations as a result, e.g., of manufacturing techniques and/or tolerances, are to be expected. Thus, exemplary embodiments should not be construed as limited to the particular shapes of regions illustrated herein but are to include deviations in shapes that result, e.g., from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and are not intended to limit the scope of the embodiments.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 illustrates a cross-sectional view of a wiring structure in accordance with exemplary embodiments.

Referring to FIG. 1, the wiring structure may include a first contact structure 202, a second contact structure 204, and a diffusion barrier layer 160. The first contact structure 202 may be electrically connected to a predetermined portion of a substrate 100. The second contact structure 204 may not be electrically connected to, e.g., may be electrically separated from, the substrate 100 and/or may not be electrically connected to the first contact structure 202.

The first contact structure 202 may include a first plug 120, a first wiring 150, a second plug 182, and a second wiring 192 on the substrate 100, e.g., sequentially stacked as different layers on the substrate 100. Accordingly, the first wiring 150 may be below the second wiring 192. The second plug 182 and the second wiring 192 may be above the first plug 120 and the first wiring 150.

The substrate 100 may include a semiconductor substrate, e.g., a silicon substrate, a germanium substrate or a silicon-germanium substrate, a silicon-on-insulator (SOI) substrate, and/or a germanium-on-insulator (GOI) substrate. In exemplary embodiment, the substrate 100 may include silicon. An isolation layer (not illustrated) defining an active region and a field region may be disposed on the substrate 100. An impurity region (not illustrated) may be disposed at an upper portion of the substrate 100.

The first plug 120 may be disposed through a first insulating interlayer 110 on the substrate 100, and may be electrically connected to the impurity region. In exemplary embodiments, a plurality of first plugs 120 may be formed. The first plug 120 may include doped polysilicon, a metal, and/or a metal silicide. In exemplary embodiments, the first insulating interlayer 110 may include an oxide, a nitride, and/or an oxynitride.

The first wiring 150 contacting the first plug 120 may be disposed through, e.g., extend through, an etch stop layer 130 and a second insulating interlayer 140. The etch stop layer 130 and the second insulating interlayer 140 may be sequentially stacked on a layer including the first insulating interlayer 110 and the first plug 120 therein. The first wiring 150 may completely overlap the first plug 120 and may be in direct contact with the first plug 120. In exemplary embodiments, the first wiring 150 may include copper, aluminum, tungsten, platinum, and/or gold.

The etch stop layer 130 may include a material having an etch selectivity with respect to the first insulating interlayer 110. For example, the etch stop layer 130 may include a silicon nitride. The second insulating interlayer 140 may include an oxide, e.g., a borosilicate glass (BSG), a borophosphosilicate glass (BPSG), an undoped silicate glass (USG), a spin on glass (SOG), a flowable oxide (FOX), a tetraethyl orthosilicate (TEOS), a plasma enhanced tetraethyl orthosilicate (PE-TEOS), a high density plasma (HDP) oxide, and/or a high temperature oxide (HTO).

The second plug 182 may be disposed through, e.g., extend through, the diffusion barrier layer 160 and a third insulating interlayer 170. The diffusion barrier layer 160 and the third insulating interlayer 170 may be sequentially stacked on the first wiring 150 and the second insulating interlayer 140, so that the second plug 182 may be connected to the first wiring 150. A plurality of second plugs 182 may be connected, e.g., directly on, one first wiring 150. In exemplary embodiments, the second plug 182 may include doped polysilicon, a metal, and/or a metal silicide. The diffusion barrier layer 160 may include a silicon nitride, a tantalum oxide, a titanium oxide, a tantalum nitride, and/or a titanium nitride. The third insulating interlayer 170 may include an oxide, e.g., a BSG, a BPSG, an USG, a FOX, a TEOS, a PE-TEOS, a HDP oxide, and/or a HTO.

The second wiring 192 may be disposed on the second plug 182 and the third insulating interlayer 170. In exemplary embodiments, the second wiring 192 may include copper, aluminum, tungsten, platinum, and/or gold.

The second contact structure 204 may include a dummy plug 184 and a dummy wiring 194. The second contact structure 204 may serve as a dummy contact structure that may not be electrically connected to the substrate 100 or to the first contact structure 202. For example, the second contact structure 204 may be electrically isolated from the both the substrate 100 and the first contact structure 202.

The dummy plug 184 may be disposed through, e.g., extend through, the diffusion barrier layer 160 and the third insulating interlayer 170, which are on the second insulating interlayer 140. Accordingly, the diffusion barrier layer 160 may have a gap through which the underlying second insulating interlayer 140 is exposed, e.g., the diffusion barrier layer 160 may not cover a portion of the second insulating interlayer 140. The dummy plug 184 may be on, e.g., in contact with, the second insulating interlayer 140. In exemplary embodiments, the dummy plug 184 may include a doped polysilicon, a metal, and/or a metal silicide. The dummy plug 184 may include a material substantially the same as that of the second plug 182. The dummy plug 184 may be formed in a region on the substrate 100 between adjacent second plugs 182 so that the second plug 182 is formed in a same layer/plane as the second plugs 182. The dummy plug 184 may be formed of a same material as the second plugs 182 and may have a same shape, e.g., width and height, as the second plugs 182. The dummy plug 184 may be in a non-overlapping relationship with the first wirings 150 formed on the substrate 100.

The dummy wiring 194 may be disposed on the dummy plug 184 and the third insulating interlayer 170. In exemplary embodiments, the dummy wiring 194 may include copper, aluminum, tungsten, platinum, and/or gold. The dummy wiring 194 may be formed in a same layer/plane as second wirings 192. The dummy wiring 194 may be formed of a same material as the second wirings 192 and may have a same shape, e.g., width and height, as ones of the second wirings 192.

In exemplary embodiments, the wiring structure may include the second contact structure 204 as well as the first contact structure 202. The dummy plug 184 of the second contact structure 204 may be disposed through the diffusion barrier layer 160 on the second insulating interlayer 140, so that impurities, e.g., hydrogen atoms remaining in the first and second insulating interlayers 110 and 140, may be outgassed, e.g., easily outgassed, through an interface of the second insulating interlayer 140 and the dummy plug 184. Accordingly, a reliability of a semiconductor device including the wiring structure may be improved.

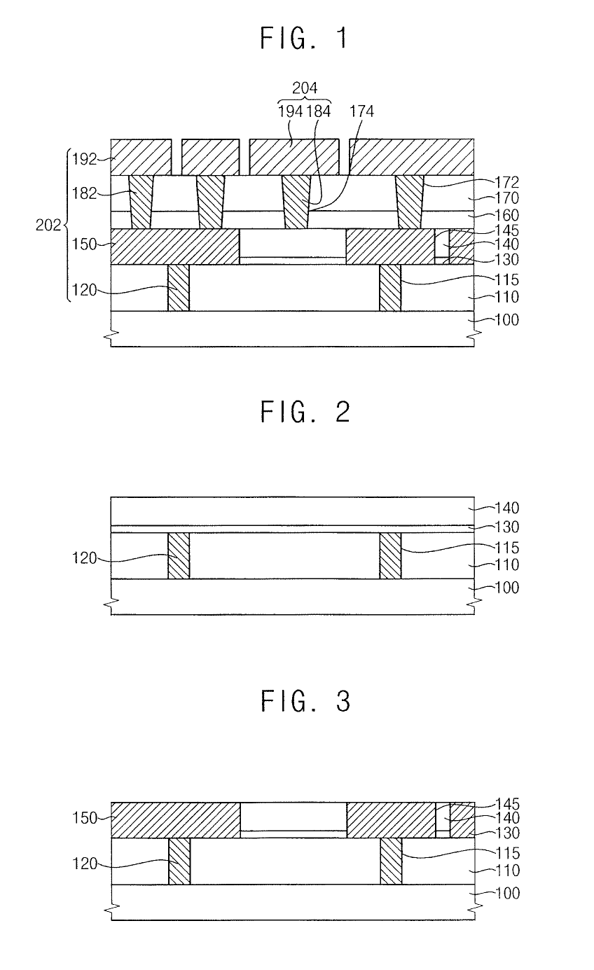

FIGS. 2 to 6 illustrate cross-sectional views of a method of manufacturing a wiring structure in accordance with exemplary embodiments.

Referring to FIG. 2, a first insulating interlayer 110 having a first plug 120 therethrough may be formed on a substrate 100.

The substrate 100 may include a semiconductor substrate, e.g., a silicon substrate, a germanium substrate or a silicon-germanium substrate, a SOI substrate and/or a GOI substrate. In exemplary embodiments, the substrate 100 may include silicon. An isolation layer (not illustrated) may be formed on the substrate 100 to define an active region and a field region. An impurity region (not illustrated) may be formed at an upper portion of the substrate 100.

The first insulating interlayer 110 may be formed using an oxide, a nitride and/or an oxynitride by a chemical vapor deposition (CVD) process, an atomic layer deposition (ALD) process and/or a sputtering process.

A first opening 115, e.g., of a plurality of first openings 115, may be formed through the first insulating interlayer 110 to expose a portion of the substrate 100. A conductive layer (not illustrated) may be formed on the exposed portion of the substrate 100 and the first insulating interlayer 110 to fill, e.g., completely fill, the first opening 115. The conductive layer may be planarized until a top surface of the first insulating interlayer 110 is exposed, so that a first plug 120, e.g., of a plurality of first plugs 120, may be formed extending through the first insulating interlayer 110. The conductive layer may be formed using polysilicon doped with impurities, a metal, a metal nitride, and/or a metal silicide.

An etch stop layer 130 and a second insulating interlayer 140 may be sequentially formed on the first insulating interlayer 110 and the first plugs 120.

The etch stop layer 130 may be formed on the first insulating interlayer 110 and the first plug 120 using a material having an etch selectivity with respect to the first insulating interlayer 110. For example, the etch stop layer 130 may have a higher etch selectivity than the first insulating interlayer 110. In exemplary embodiments, the etch stop layer 130 may be formed using a silicon nitride.

The second insulating interlayer 140 may be formed on the etch stop layer 130 using an oxide, e.g., a BSG, a BPSG, an USG, a FOX, a TEOS, a PE-TEOS, a HDP oxide, and/or a HTO by a CVD process, an ALD process, and/or a sputtering process.

Referring to FIG. 3, a second opening 145, e.g., of a plurality of second openings 145, may be formed through the second insulating interlayer 140 and the etch stop layer 130 to expose the first plug 120. For example, a portion of the second insulating interlayer 140 may be etched until a portion of the etch stop layer 130 is exposed, and the exposed portion of the etch stop layer 130 may be removed to expose a portion of a top surface of the first plug 120.

A conductive layer (not illustrated) may be formed on the first and second insulating interlayers 110 and 140 and the exposed top surface of the first plug 120 to fill the second opening 145. Thereafter, the conductive layer may be planarized until a top surface of the second insulating interlayer 140 may be exposed, so that a first wiring 150 electrically connected to the first plug 120 may be formed in the second opening 145. In exemplary embodiments, the conductive layer may be formed using copper, aluminum, tungsten, platinum, and/or gold. The planarization process may be performed using a chemical mechanical planarization (CMP) process or an etch back process.

When the conductive layer is formed using copper, a barrier metal layer (not shown) or a seed layer may be further formed on the first insulating interlayer 110, the exposed top surface of the first plug 120, and a sidewall of the second opening 145. The barrier metal layer may prevent copper atoms from diffusing from the first wiring 150 to the first and second insulating interlayers 110 and 140. The barrier metal layer may be formed using titanium, titanium nitride, tantalum, and/or tantalum nitride.

Referring to FIG. 4, a diffusion barrier layer 160 and a third insulating interlayer 170 may be sequentially formed on the first wiring 150 and the second insulating interlayer 140.

In exemplary embodiments, the diffusion barrier layer 160 may be formed using a silicon nitride, a tantalum oxide, a titanium oxide, a tantalum nitride, and/or a titanium nitride by a CVD process, an ALD process, and/or a sputtering process. For example, when the first wiring 150 is formed using copper, copper atoms may electromigrate, e.g., gradually move, to the insulating interlayers including silicon oxide, thereby deteriorating a reliability of a semiconductor device. However, the diffusion barrier layer 160 may reduce the possibly of and/or prevent the electromigration of copper atoms.

The third insulating interlayer 170 may be formed on the diffusion barrier layer 160 using an oxide, e.g., a BSG, a BPSG, an USG, a FOX, a TEOS, a PE-TEOS, a HDP oxide, and/or a FITO by a CVD process, an ALD process, and/or a sputtering process.

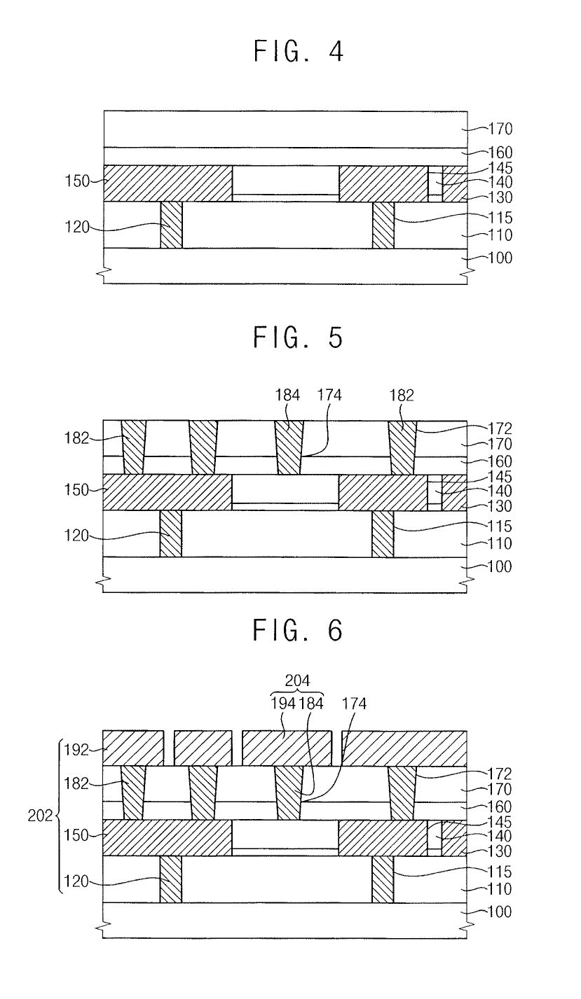

Referring to FIG. 5, a second plug 182, e.g., of a plurality of second plugs 182, may be formed through the third insulating interlayer 170 and the diffusion barrier layer 160 to contact ones of the first wirings 150. A dummy plug 184 may be formed through the third insulating interlayer 170 and the diffusion barrier layer 160 to contact the second insulating interlayer 140 so that the dummy plug 184 may be spaced apart from the plurality of first wirings 150.

The third insulating interlayer 170 and the diffusion barrier layer 160 may be sequentially etched to form a third opening 172, e.g., of a plurality of third openings 172, exposing a top surface of the first wiring 150 and a fourth opening 174 exposing a top surface of the second insulating interlayer 140. In exemplary embodiments, a plurality of third openings 172 and a plurality of fourth openings 174 may be formed.

A conductive layer (not illustrated) may be formed to fill the third opening 172 and the fourth opening 174. Thereafter, the conductive layer may be planarized until a top surface of the third insulating interlayer 170 is exposed, so that the second plug 182 and the dummy plug 184 may be formed, e.g., simultaneously formed, to fill the third opening 172 and the fourth opening 174, respectively. In exemplary embodiments, the conductive layer may be formed using doped polysilicon, a metal and/or a metal silicide, and the planarization process may be performed using a CMP process or an etch back process. In exemplary embodiments, the second plug 182 and the dummy plug 184 may be formed using substantially the same material.

Therefore, the second plug 182 may be formed through the third insulating interlayer 170 and the diffusion barrier layer 160 to contact the first wiring 150. The dummy plug 184 may be formed through the third insulating interlayer 170 and the diffusion barrier layer 160 to contact the second insulating interlayer 140.

Alternatively, after forming the second plug 182 filling the third opening 172, the dummy plug 184 filling the fourth opening 174 may be formed separately. In this case, the dummy plug 184 may be formed using a material different from that of the second plug 182. Further, the dummy plug 184 may have a height substantially larger than that of the second plug 182.

Referring to FIG. 6, a second wiring 192 contacting the second plug 182 and a dummy wiring 194 contacting the dummy plug 184 may be formed, e.g., simultaneously formed, on the third insulating interlayer 170.

After forming a conductive layer (not illustrated) on the second plug 182, the dummy plug 184 and the third insulating interlayer 170, the conductive layer may be patterned to form the second wiring 192 contacting the second plug 182 and the dummy wiring 194 contacting the dummy plug 184. The conductive layer may be formed using copper, aluminum, tungsten, platinum, and/or gold by a CVD process, an ALD process, and/or a sputtering process. The second wiring 192 and the dummy wiring 194 may be formed not to be electrically connected to each other.

By performing the afore-mentioned processes, a wiring structure may be manufactured. The wiring structure may include the first contact structure 202 and the second contact structure 204, and the second contact structure 204 may serve as a dummy contact structure including the dummy plug 184 and the dummy wiring 194. The dummy plug 184 of the second contact structure 204 may be formed through the diffusion barrier layer 160 on the second insulating interlayer 140, so that impurities, e.g., hydrogen atoms remaining in the insulating interlayers 110 and 140, may be outgassed, e.g., released in a gaseous form, through interface of the second insulating interlayer 140 and the dummy plug 184. Accordingly, a reliability of a semiconductor device including the wiring structure may be improved.

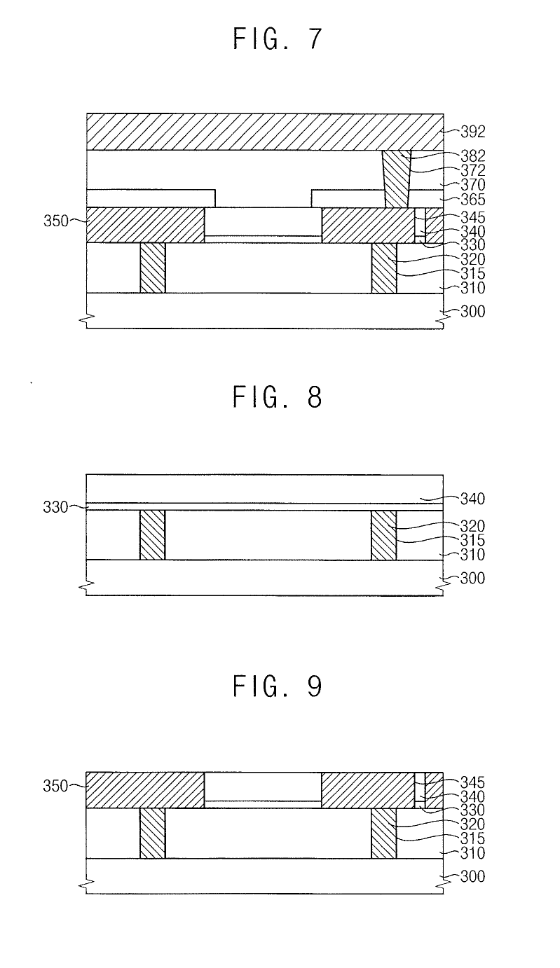

FIG. 7 illustrates a cross-sectional view of a wiring structure in accordance with exemplary embodiments.

Referring to FIG. 7, the wiring structure may include a first plug 320, a first wiring 350, a diffusion barrier layer pattern 365, a second plug 382, and a second wiring 392, which may be stacked on a substrate 300. The wiring structure of FIG. 7 may be similar to the wiring structure illustrated in FIG. 1, and differences therebetween are described.

The substrate 300 may include a semiconductor substrate, e.g., a silicon substrate, a germanium substrate or a silicon-germanium substrate, a SOI substrate, and/or a GOI substrate. In exemplary embodiments, the substrate 300 may include silicon. An isolation layer (not illustrated) defining an active region and a field region may be disposed on the substrate 300. An impurity region (not illustrated) may be disposed at an upper portion of the substrate 300.

The first plug 320 may be disposed through a first insulating interlayer 310 on the substrate 300 to be electrically connected to the impurity region. In exemplary embodiments, a plurality of first plugs 320 may be formed. The first plug 320 may include doped polysilicon, a metal, and/or a metal silicide. In exemplary embodiments, the first insulating interlayer 310 may include an oxide, a nitride, and/or an oxynitride.

The first wiring 350 contacting the first plug 320 may be disposed through an etch stop layer 330 and a second insulating interlayer 340 which may be sequentially stacked on the first insulating interlayer 310 and the first plug 320. In exemplary embodiments, the first wiring 350 may include copper, aluminum, tungsten, platinum, and/or gold.

The etch stop layer 330 may include a material having an etch selectivity with respect to the first insulating interlayer 310. For example, the etch stop layer 330 may include a silicon nitride. The second insulating interlayer 340 may include an oxide, e.g., a BSG, a BPSG, an USG, a SOG, a FOX, a TEOS, a PE-TEOS, a HDP oxide, and/or a HTO.

The diffusion barrier layer pattern 365 may be disposed on, e.g., directly on, the first wiring 350 and a portion of the second insulating interlayer 340. The diffusion barrier layer pattern 365 may also be excluded on another portion of the second insulating interlayer 340 surrounding the portion of the second insulating interlayer 340 on which the diffusion barrier layer pattern 365 is formed. Accordingly, there may be at least one gap in the diffusion barrier layer pattern 365, e.g., the diffusion barrier layer pattern 365 may not cover the other portion of the second insulating interlayer 340. The diffusion barrier layer pattern 365 may also cover the first wiring 350 sufficiently, e.g., completely covering, and also cover the portion of the second insulating interlayer 340 that is adjacent to the gap in the diffusion barrier layer pattern 365. In exemplary embodiments, the diffusion barrier layer pattern 365 may include a silicon nitride, a tantalum oxide, a titanium oxide, a tantalum nitride, and/or a titanium nitride.

For example, when the first wiring 350 includes copper, the diffusion barrier layer pattern 365 may sufficiently cover, e.g., completely cover, the first wiring 350 to reduce the possibility of and/or prevent an electromigration of copper atoms. The diffusion barrier layer pattern 365 may be disposed on the portion of the second insulating interlayer 340, so that another portion of the second insulating interlayer 340 not covered by the diffusion barrier layer pattern 365 may exist in an area where the first wirings 350 are excluded thereunder. Accordingly, impurities, e.g., hydrogen atoms generated in the insulating interlayers 310 and 340 may be outgassed, e.g., easily outgassed, through the portion of the second insulating interlayer 340 not covered by the diffusion barrier layer pattern 365.

In accordance with an exemplary embodiment, when the diffusion barrier layer pattern 365 is formed, the second contact structure 204 may be excluded. Alternatively, the second contact structure 204 may be formed directly on the other portion of the second insulating interlayer 340 on which the diffusion barrier layer pattern 365 is excluded.

The second plug 382 may be disposed through both the diffusion barrier layer pattern 365 and the third insulating interlayer 370 to contact the first wiring 350. In exemplary embodiments, the second plug 382 may include doped polysilicon, a metal, and/or a metal silicide. The third insulating interlayer 370 may be disposed on the diffusion barrier layer pattern 365 and the second insulating interlayer 340. The third insulating interlayer 370 may include an oxide, e.g., a BSG, a BPSG, an USG, a FOX, a TEOS, a PE-TEOS, a HDP oxide, and/or a HTO.

The second wiring 392 may be disposed on the second plug 382 and the third insulating interlayer 370 so as to be above the second plug 382. In exemplary embodiments, the second wiring 392 may include copper, aluminum, tungsten, platinum, and/or gold. The second wirings 392 maybe in an overlapping relationship with portions of the substrate 300 that include the diffusion barrier layer pattern 365 and with portions of the substrate 300 that exclude the diffusion barrier layer pattern 365. In another embodiment, the second wirings 392 may be in a non-overlapping relationship with the portion of the substrate 300 where the diffusion barrier layer pattern 365 is excluded.

In exemplary embodiments, the wiring structure may include the diffusion barrier layer pattern 365 partially disposed on the second insulating interlayer 340, so that a portion of the second insulating interlayer 340 may not be covered by the diffusion barrier layer pattern 365. Therefore, impurities, e.g., hydrogen atoms remaining in the insulating interlayers may be outgassed, e.g., easily outgassed, through the portion of the second insulating interlayer 340 not covered by the diffusion barrier layer pattern 365. Accordingly, a reliability of a semiconductor device including the wiring structure may be improved.

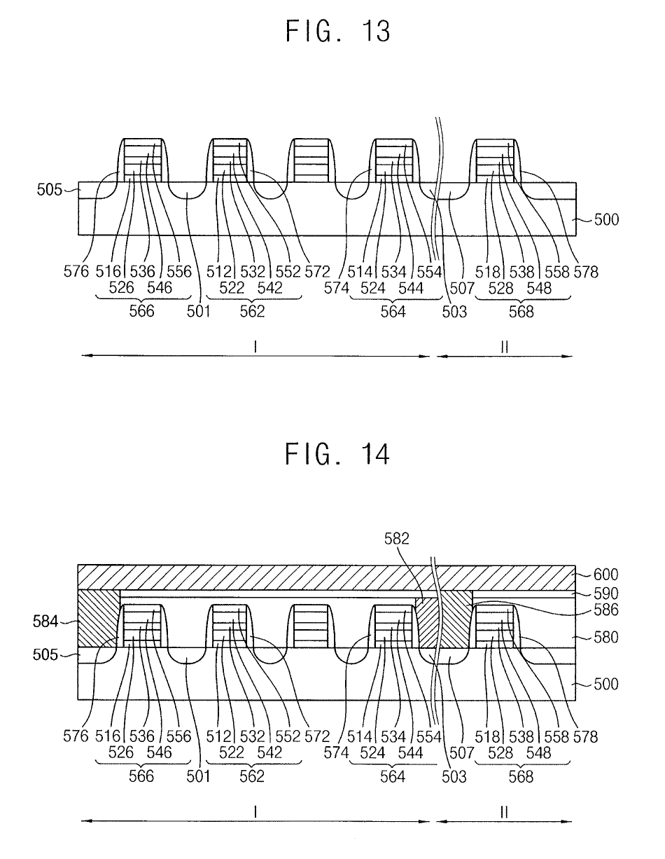

FIGS. 8 to 12 illustrate cross-sectional views depicting stages in an exemplary method of manufacturing the wiring structure illustrated in FIG. 7. Referring to FIG. 8, a first insulating interlayer 310 having a first plug 320 therethrough may be formed on a substrate 300.

The substrate 300 may include a semiconductor substrate, e.g., a silicon substrate, a germanium substrate or a silicon-germanium substrate, a SOI substrate, and/or a GOI substrate. In exemplary embodiments, the substrate 300 may include silicon. An isolation layer (not illustrated) may be formed on the substrate 300 to define an active region and a field region. An impurity region (not illustrated) may be formed at an upper portion of the substrate 300.

The first insulating interlayer 310 may be formed using an oxide, a nitride, and/or an oxynitride by a CVD process, an ALD process, and/or a sputtering process.

A first opening 315 may be formed through the first insulating interlayer 310 to expose a top surface of the substrate 300, and a conductive layer (not illustrated) may be formed on the exposed top surface of the substrate 300 and the first insulating interlayer 310 to fill the first opening 315. The conductive layer may be planarized until a top surface of the first insulating interlayer 310 is exposed, so that a first plug 320 may be formed through the first insulating interlayer 310. The conductive layer may be formed using polysilicon doped with impurities, a metal, a metal nitride, and/or a metal silicide.

An etch stop layer 330 and a second insulating interlayer 340 may be sequentially formed on the first insulating interlayer 310 and the first plug 320.

The etch stop layer 330 may be formed on the first insulating interlayer 310 and the first plug 320 using a material having an etch selectivity with respect to the first insulating interlayer 310. In exemplary embodiments, the etch stop layer 330 may be formed using a silicon nitride.

The second insulating interlayer 340 may be formed on the etch stop layer 330 using an oxide, e.g., a BSG, a BPSG, an USG, a FOX, a TEOS, a PE-TEOS, a HDP oxide, and/or a HTO by a CVD process, an ALD process, and/or a sputtering process.

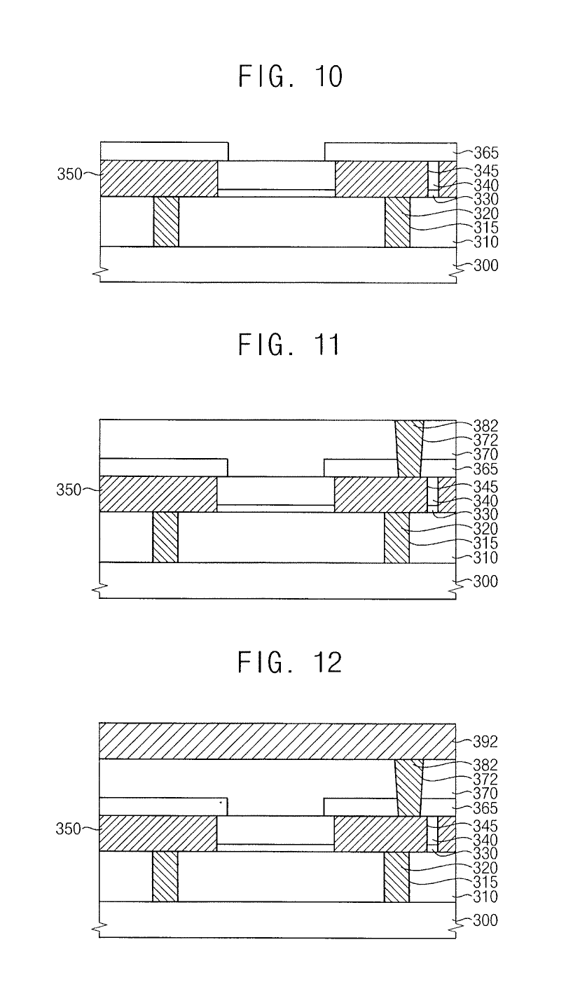

Referring to FIG. 9, a second opening 345 may be formed through the second insulating interlayer 340 and the etch stop layer 330 to expose the first plug 320 and a portion of the first insulating interlayer 310. For example, the second insulating interlayer 340 may be partially etched until a portion of the etch stop layer 330 is exposed. The exposed portion of the etch stop layer 330 may be removed to expose the portion of the first insulating interlayer 310 and the first plug 320.

A conductive layer (not illustrated) may be formed on the first and second insulating interlayers 310 and 340 and the exposed first plug 320 to fill the second opening 345. The conductive layer may be planarized until a top surface of the second insulating interlayer 340 may be exposed, so that a first wiring 350 electrically connected to the first plug 320 may be formed in the second opening 345. In exemplary embodiments, the conductive layer may be formed using copper, aluminum, tungsten, platinum, and/or gold. The planarization process may be performed using a CMP process or an etch back process.

When the conductive layer is formed using copper, a barrier metal layer may be further formed on the first insulating interlayer 310, the first plug 320, and a sidewall of the second opening 345.

Referring to FIG. 10, a diffusion barrier layer pattern 365 may be formed on the first wiring 350 and a portion of the second insulating interlayer 340.

In exemplary embodiments, after forming a diffusion barrier layer (not illustrated) on the first wiring 350 and the second insulating interlayer 340, the diffusion barrier layer may be patterned by a photolithography process to form the diffusion barrier layer pattern 365 sufficiently covering, e.g., completely cover, the first wiring 350. In some exemplary embodiments, a dry etching process or a wet etching process may be performed on the diffusion barrier layer on the first wiring 350 and the second insulating interlayer 340, so that a diffusion barrier layer pattern 365 may be formed to sufficiently cover the first wiring 350. In exemplary embodiments, the diffusion barrier layer may be formed using a silicon nitride, a tantalum oxide, a titanium oxide, a tantalum nitride, and/or a titanium nitride by a CVD process, an ALD process, and/or a sputtering process.

Referring to FIG. 12, a third insulating interlayer 370 may be formed on the diffusion barrier layer pattern 365 and the second insulating interlayer 340 using an oxide, e.g., a BSG, a BPSG, an USG, a FOX, a TEOS, a PE-TEOS, a HDP oxide, and/or a HTO by a CVD process, an ALD process, and/or a sputtering process.

A second plug 382 may be formed through the third insulating interlayer 370 and the diffusion barrier layer pattern 365 to contact the first wiring 350. For example, the third insulating interlayer 370 and the diffusion barrier layer pattern 365 may be sequentially etched to form a third opening 372 exposing a top surface of the first wiring 350. A conductive layer (not illustrated) may be formed to fill the third opening 372, and the conductive layer may be planarized until a top surface of the third insulating interlayer 370 is exposed. Accordingly, the second plug 382 filling, e.g., completely filling, the third opening 172 may be formed. In exemplary embodiments, the conductive layer may be formed using doped polysilicon, a metal, and/or a metal silicide. The planarization process may be performed using a CMP process or an etch back process.

Referring to FIG. 12, a second wiring 392 contacting the second plug 382 may be formed on the third insulating interlayer 370. For example, after forming a conductive layer (not illustrated) on the second plug 382 and the third insulating interlayer 370, the conductive layer may be patterned to form the second wiring 392 contacting the second plug 382. The conductive layer may be formed using copper, aluminum, tungsten, platinum, and/or gold by a CVD process, an ALD process, and/or a sputtering process.

By performing the afore-mentioned processes, the wiring structure may be manufactured. The wiring structure may include the diffusion barrier layer pattern 365 partially on the second insulating interlayer 340, i.e., only on a portion of the second insulating interlayer 340, so that another portion of the second insulating interlayer 340 may not be covered by the diffusion barrier layer pattern 365. Therefore, impurities, e.g., hydrogen atoms remaining in the first and insulating interlayers 310 and 340, may be outgassed, e.g., easily outgassed, through the portion of the second insulating interlayer 340 not covered by the diffusion barrier layer 365. Accordingly, a reliability of a semiconductor device including the wiring structure may be improved.

FIGS. 13 to 16 illustrate cross-sectional views depicting stages in a method of manufacturing a semiconductor device in accordance with exemplary embodiments.

Referring to FIG. 13, an isolation layer (not illustrated) may be formed on a substrate 500 to divide the substrate 500 into an active region and a field region. A first gate structure 562, a second gate structure 564, a third gate structure 566, and a fourth gate structure 568 may be formed on the substrate 500.

In exemplary embodiments, a tunnel insulation layer, a floating gate layer, a dielectric layer, a control gate layer, and a gate mask layer may be sequentially formed on the substrate 500. The tunnel insulation layer, the floating gate layer, the dielectric layer, the control gate layer, and the gate mask layer may be patterned to form the first to fourth gate structures 562, 564, 566, and 568 on the substrate 500.

The first to third gate structures 562, 564, and 566 may be formed on the substrate 500 in a first region I. The fourth gate structure 568 may be formed on the substrate 500 in a second region II. The first region I may be a cell region, and the second region II may be a peripheral region. In exemplary embodiments, a plurality of first gate structures 562 may be formed to be spaced apart from each other along a first direction between the second gate structure 564 and the third gate structure 566. In exemplary embodiments, 16 or 32 first gate structures 562 may be formed.

The first to fourth gate structures 562, 564, 566, and 568 may include first to fourth insulation layer patterns 512, 514, 516, and 518, first to fourth floating gates 522, 524, 526, and 528, first to fourth dielectric layer patterns 532, 534, 536, and 538, first to fourth control gates 542, 544, 546, and 548, and first to fourth gate masks 552, 554, 556, and 558, respectively. Lateral sides of the first to fourth insulation layer patterns 512, 514, 516, and 518, first to fourth floating gates 522, 524, 526, and 528, first to fourth dielectric layer patterns 532, 534, 536, and 538, first to fourth control gates 542, 544, 546, and 548, and first to fourth gate masks 552, 554, 556, and 558, respectively, may be vertically aligned, e.g., may form continuous lateral sides of first to fourth gate structures 562, 564, 566, and 568, respectively.

In exemplary embodiments, the tunnel insulation layer patterns 512, 514, 516, and 518 may have an island shape, e.g., spaced apart from each other on, e.g., directly on, the substrate 500. In exemplary embodiments, the floating gates 522, 524, 526, and 528 may have an island shape, e.g., spaced apart from each other. The floating gates 522, 524, 526, and 528 may be on, e.g., directly on, the tunnel insulation layer patterns 512, 514, 516, and 518, respectively. Each of the first to fourth dielectric layer patterns 532, 534, 536, and 538 and each of the first to fourth control gates 542, 544, 546, and 548 may extend along a second direction perpendicular to the first direction.

A spacer layer covering the first to fourth gate structures 562, 564, 566, and 568, e.g., the lateral sides thereof, may be formed. An anisotropic etching process may be performed to form first to fourth spacers 572, 574, 576, and 578 on sidewalls of the first to fourth gate structures 562, 564, 566, and 568, respectively. The spacer layer may be formed using a nitride, e.g., a silicon nitride.

Impurities may be implanted into upper portions of the substrate 500 by using the first to fourth gate structures 562, 564, 566, and 568 and the first to fourth spacers 572, 574, 576, and 578 as an ion implantation mask. Therefore, first to fourth impurity regions 501, 503, 505, and 507 may be formed at the upper portions of the substrate 500 adjacent to the gate structures 562, 564, 566, and 568, respectively. The first impurity region 501 may formed at the upper portion of the substrate 500 adjacent to the first gate structure 562, the second impurity region 503 may formed at the upper portion of the substrate 500 adjacent to the second gate structure 564, the third impurity region 505 may formed at the upper portion of the substrate 500 adjacent to the third gate structure 566, and the fourth impurity region 507 may formed at the upper portion of the substrate 500 adjacent to the fourth gate structure 568. The fourth impurity region 507 may be formed in, e.g., only in, the second region II.

The first to third control gates 542, 544, and 546 of the first to third gate structures 562, 564, and 566, respectively, may be formed on the substrate 500 in the first region I. For example, the first to third control gates 542, 544, and 546 may serve as a word line, a ground selection line (GSL), and a string selection line (SSL), respectively. However, embodiments are not limited thereto.

The tunnel insulation layer may be formed by performing a thermal oxidation process on the substrate 500. In exemplary embodiments, a surface of the substrate 500 including silicon may be thermally oxidized to form the tunnel insulation layer containing silicon oxide. In this case, a dangling bond may be generated in the tunnel insulation layer.

Referring to FIG. 14, a first insulating interlayer 580 may be formed on the substrate 500 to cover the gate structures 562, 564, 566, and 568. The first insulating interlayer 580 may be formed using an oxide, e.g., a BPSG, an USG, and/or a SOG.

A common source line (CSL) 582 may be formed through the first insulating interlayer 582 to be electrically connected to the second impurity region 503. The CSL 582 may be formed using doped polysilicon, a metal, a metal nitride, and/or a metal silicide.

A second insulating interlayer 590 may be formed on the first insulating interlayer 580 and the CSL 582. The second insulating interlayer 590 may be formed using an oxide, e.g., a BPSG, an USG, and/or a SOG.

A bit line contact 584 may be formed through the first and second insulating interlayers 580 and 590 in the first region I. The bit line contact 584 may be electrically connected to the third impurity region 505. The bit line contact 584 may be formed using doped polysilicon, a metal, a metal nitride, and/or a metal silicide. A first plug 586 may be formed through the first and second insulating interlayers 580 and 590 in the second region II. The first plug 586 may be electrically connected to the fourth impurity region 507.

A bit line 600 may be formed on the second insulating interlayer 590 to be electrically connected to the bit line contact 584. In exemplary embodiments, the bit line 600 may extend along the first direction. The bit line 600 may be formed using doped silicon, a metal, a metal nitride and/or a metal silicide. According to an exemplary embodiment, the bit line 600 may also be formed in the second region II to be electrically connected to the first plug 586.

Referring to FIG. 15, processes substantially the same as or similar to those illustrated with reference to FIGS. 2 to 3 may be performed.

For example, a third insulating interlayer 610 covering the bit line 600 may be formed on the second insulating interlayer 590. A first opening (not illustrated) may be formed through the third insulating interlayer 610 to expose the bit line 600. A conductive layer may be formed on the bit line 600 and the second insulating interlayer 590 to fill the first opening. An upper portion of the conductive layer may be planarized until a top surface of the second insulating interlayer 590 is exposed, so that a second plug 620 may be formed to be electrically connected to the bit line 600. An etch stop layer 630 and a fourth insulating interlayer 640 may be sequentially formed on the second insulating interlayer 590 and the second plug 620, and a second opening (not illustrated) may be formed through the fourth insulating interlayer 640 and the etch stop layer 630 to expose the second plug 620.

A metal wiring layer (not illustrated) may be formed on the exposed second plug 620, the fourth insulating interlayer 640 and an inner wall of the second opening to sufficiently fill, e.g., completely fill, the second opening, and the metal wiring layer may be planarized using a CMP process or an etch back process until a top surface of the fourth insulating interlayer 640 is exposed, thereby forming a first wiring 650.

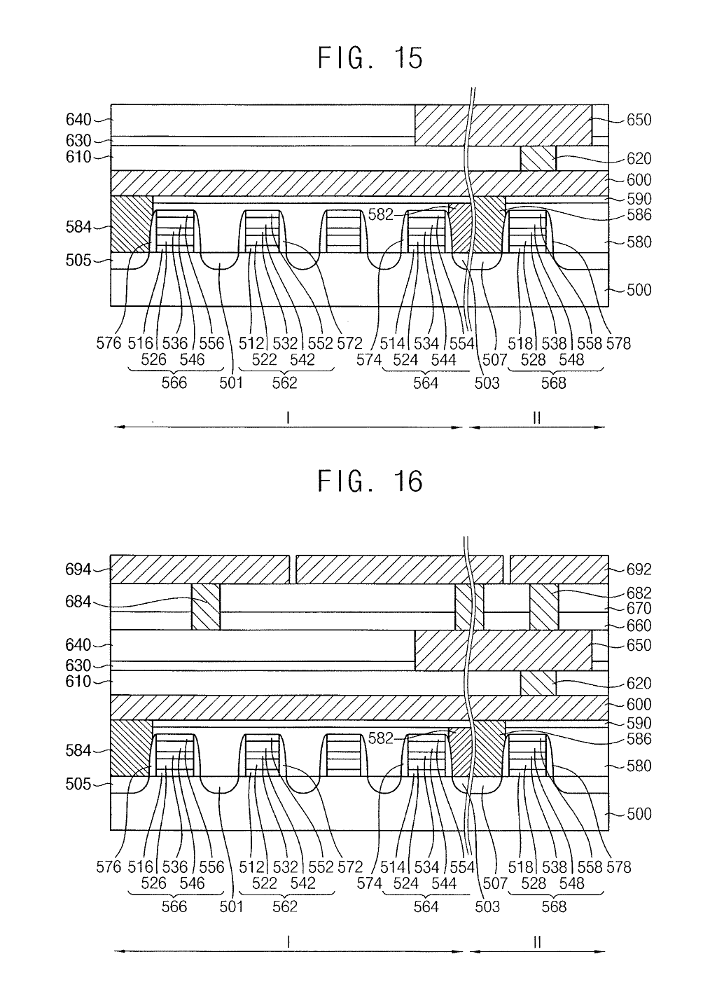

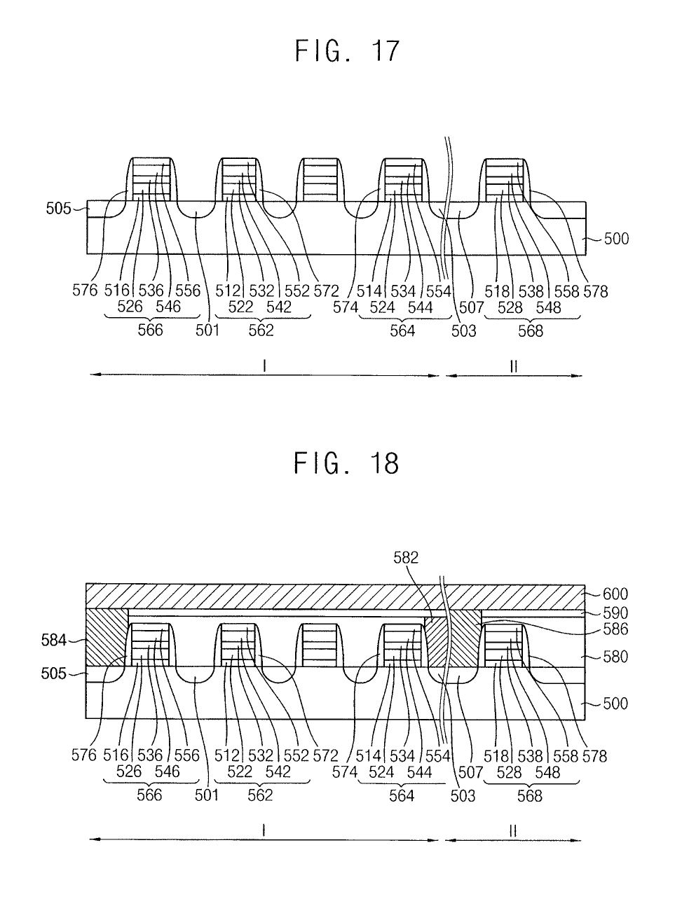

Referring to FIG. 16, processes substantially the same as or similar to those illustrated with reference to FIGS. 4 to 6 may be performed.

For example, a diffusion barrier layer 660 and a fifth insulating interlayer 670 may be formed sequentially on the first wiring 650 and the fourth insulating interlayer 640. The fifth insulating interlayer 670 and the diffusion barrier layer 660 may be etched to form a third opening (not illustrated) exposing a top surface of the first wiring 650 and a fourth opening (not illustrated) exposing a top surface of fourth insulating interlayer 640.

A conductive layer (not illustrated) filling the third opening and the fourth opening may be formed. The conductive layer may be planarized until a top surface of the fifth insulating interlayer 670 is exposed, so that a third plug 682 and a dummy plug 684 may be formed to fill the third opening and the fourth opening, respectively.

After forming a conductive layer (not illustrated) on the third plug 682, the dummy plug 684 and the fifth insulating interlayer 670, the conductive layer may be patterned to form a second wiring 692 contacting the third plug 682 and a dummy wiring 694 contacting the dummy plug 684. The second wiring 692 and the dummy wiring 694 may be electrically isolated from each other.

By performing the afore-mentioned processes, the semiconductor device may be manufactured.

FIGS. 17 to 20 illustrate cross-sectional views depicting stages in a method of manufacturing a semiconductor device in accordance with exemplary embodiments. The method may be substantially similar to those illustrated with reference to FIGS. 13 to 16. Thus, like numerals refer to like elements, and the difference between the two methods are illustrated herein. Further the processes may be substantially the same as or similar to those illustrated with respect to FIGS. 8 to 12.

Referring to FIG. 17, a first gate structure 562, a second gate structure 564, a third gate structure 566 and a fourth gate structure 568 may be formed on a substrate 500. The first to third gate structures 562, 564, and 566 may be formed on the substrate 500 in a first region I, and the fourth gate structure 568 may be formed on the substrate 500 in a second region II. The first to fourth gate structures 562, 564, 566, and 568 may include first to fourth insulation layer patterns 512, 514, 516, and 518, first to fourth floating gates 522, 524, 526 and 528, first to fourth dielectric layer patterns 532, 534, 536, and 538, first to fourth control gates 542, 544, 546, and 548, and first to fourth gate masks 552, 554, 556 and 558, respectively. First to fourth spacers 572, 574, 576, and 578 may be formed on sidewalls of the first to fourth gate structures 562, 564, 566, and 568, respectively. First to fourth impurity regions 501, 503, 505, and 507 may be formed at upper portions of the substrate 500 adjacent to the gate structures 562, 564, 566 and 568, respectively.

Referring to FIG. 18, a first insulating interlayer 580 may be formed on the substrate 500 to cover the gate structures 562, 564, 566, and 568. A common source line (CSL) 582 may be formed through the first insulating interlayer 580 to be electrically connected to a second impurity region 503. A second insulating interlayer 590 may be formed on the first insulating interlayer 580 and the CSL 582. A bit line contact 584 may be formed through the first and second insulating interlayers 580 and 590 to be electrically connected to a third impurity region 505, and a first plug 586 may be formed through the first and second insulating interlayers 580 and 590 to be electrically connected to a fourth impurity region 507. A bit line 600 may be formed on the second insulating interlayer 590 to be electrically connected to the bit line contact 584.

Referring to FIG. 19, a third insulating interlayer 610 covering the bit line 600 may be formed on the second insulating interlayer 590. A first opening (not illustrated) may be formed through the third insulating interlayer 610 to expose the bit line 600. A conductive layer may be formed on the bit line 600 and the second insulating interlayer 590 to fill the first opening. An upper portion of the conductive layer may be planarized until a top surface of the second insulating interlayer 590 is exposed, so that a second plug 620 electrically connected to the bit line 600 may be formed. An etch stop layer 630 and a fourth insulating interlayer 640 may be sequentially formed on the second insulating interlayer 590 and the second plug 620. A second opening (not illustrated) may be formed through the fourth insulating interlayer 640 and the etch stop layer 630 to expose the second plug 620.

A metal wiring layer (not illustrated) may be formed on the exposed second plug 620, the fourth insulating interlayer 640, and an inner wall of the second opening to sufficiently fill, e.g., completely fill, the second opening. The metal wiring layer may be planarized by using a CMP process or an etch back process until a top surface of the fourth insulating interlayer 640 is exposed, thereby forming a first wiring 650.

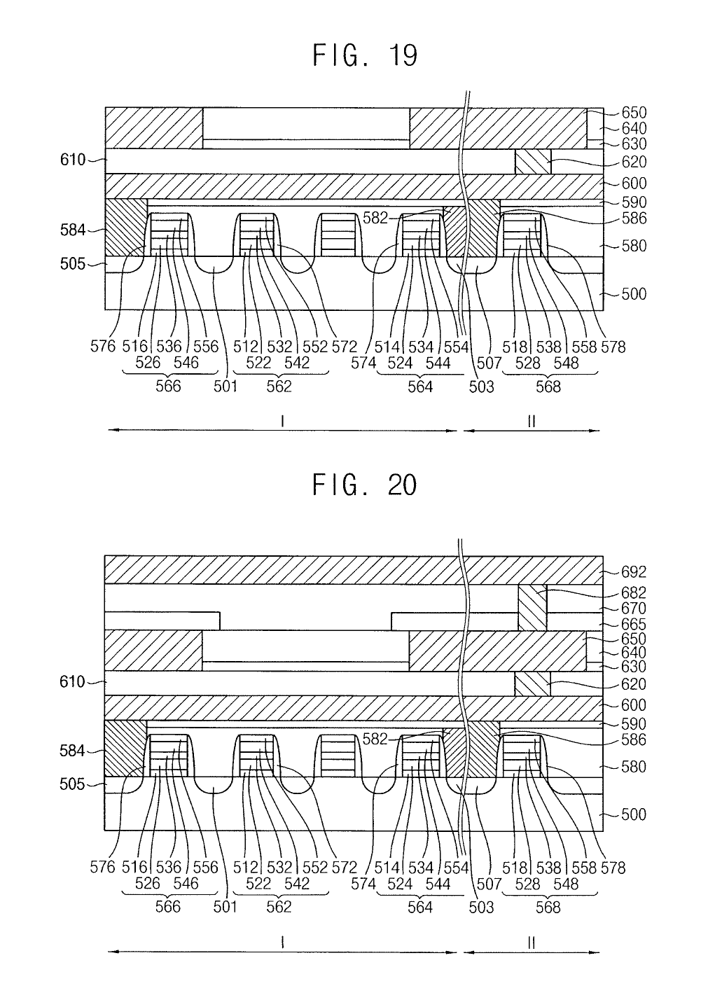

Referring to FIG. 20, after forming a diffusion barrier layer (not illustrated) on the first wiring 650 and the fourth insulating interlayer 640, the diffusion barrier layer may be partially removed to form a diffusion barrier layer pattern 665 sufficiently covering, e.g., completely covering, the first wiring 650. In exemplary embodiments, the diffusion barrier layer pattern 665 may be formed by a photolithography process, a dry etching process, and/or a wet etching process.

A fifth insulating interlayer 670 may be formed on the diffusion barrier layer pattern 665 and the fourth insulating interlayer 640, and a third opening (not illustrated) may be formed through the fifth insulating interlayer 670 and the diffusion barrier layer pattern 665 to expose a top surface of the first wiring 650. A conductive layer filling the third opening may be formed, and the conductive layer may be planarized until a top surface of the fifth insulating interlayer 670 is exposed, thereby forming a third plug 682 filling the third opening.

After forming a conductive layer (not illustrated) on the third plug 682 and the fifth insulating interlayer 670, the conductive layer may be patterned to form a second wiring 692 contacting the third plug 682.

By performing the afore-mentioned processes, the semiconductor device may be manufactured.

By way of summation and review, gate structures of semiconductor devices may include silicon oxide layers. For example, DRAM devices may include gate insulation layers containing silicon oxide and flash memory devices may include tunnel insulation layers containing silicon oxide. The silicon oxide layer may be formed by performing a thermal oxidation process on a substrate including silicon. In some instances, outer-shell electrons of silicon atoms at an interface between the substrate and the silicon oxide layer may not be bonded, so that a dangling bond may be generated. The dangling bond may trap electrons so that a threshold voltage of a transistor including the silicon oxide layer as a gate insulation layer may increase and/or data retention characteristics may be deteriorated.

An insulating interlayer of a semiconductor device may be formed using a tetraethyl orthosilicate (TEOS) and/or a high density plasma (HDP) oxide by a chemical vapor deposition (CVD) process. Accordingly, impurities such as hydrogen bonds may be generated in the insulating interlayer. A bond strength of the hydrogen bonds may be weak so that the hydrogen atoms may migrate to adjacent layers, e.g., toward a gate insulation layer to deteriorate electrical characteristics of the gate insulating layer and/or the semiconductor device.

Therefore, various methods, e.g., a heat treatment process, for removing the dangling bond and hydrogen have been developed. For example, after forming the insulating interlayer, a heat treatment process may be used and/or may be necessary for outgassing the hydrogen atoms. However, layers formed during the manufacture of the semiconductor device, e.g., a diffusion barrier layer for reducing the possibility of and/or preventing a migration of a wiring structure may interrupt a heat treatment.

In some instances, a diffusion barrier layer including, e.g., a silicon nitride, may be formed on the wirings, e.g., copper wirings, to prevent atoms, e.g., the copper atoms in the copper wirings, from diffusing into adjacent layers. However, a diffusion rate of the hydrogen atoms in the silicon nitride may be slow. Accordingly, the hydrogen atoms in the insulating interlayer may not be easily outgassed through the diffusion barrier layer including, e.g., the silicon nitride.

In contrast, embodiments, e.g., the exemplary embodiments discussed above, provide ways to reduce and/or remove the dangling bond and movement impurities. For example, embodiments relate to wiring structures including a diffusion barrier layer pattern and methods of manufacturing the same. When the metal wirings are formed, a dummy contact structure including a dummy plug and a dummy wiring may be further formed, so that the hydrogen atoms may be easily outgassed through the dummy contact structure. Additionally, a portion of the diffusion barrier layer may be removed to form an outgassing path for the hydrogen atoms.

Exemplary embodiments relate to a wiring structure having an effective structure for removing dangling bonds and hydrogen atoms. Exemplary embodiments also relate to a method of manufacturing the wiring structure

Exemplary embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A wiring structure, comprising:
a first plug extending through a first insulating interlayer, the first insulating interlayer being on a substrate;
a first wiring extending through a second insulating interlayer, the second insulating interlayer being on the first insulating interlayer and the first wiring being electrically connected to the first plug;
a diffusion barrier layer pattern on the first wiring and on the second insulating interlayer, a portion of the second insulating interlayer being free of being covered by the diffusion barrier layer pattern;
a second plug extending through the diffusion barrier layer pattern, the second plug being in contact with the first wiring; and
a second wiring electrically connected to the second plug.

2. The wiring structure as claimed in claim 1, wherein an etch stop layer is between the first insulating interlayer and the second insulating interlayer.

3. The wiring structure as claimed in claim 1, further comprising a third insulating interlayer between the diffusion barrier layer pattern and the second wiring, the second plug extending through both the third insulating interlayer and the diffusion barrier layer pattern.

4. The wiring structure as claimed in claim 1, wherein the first wiring includes at least one selected from copper, aluminum, tungsten, platinum, and gold.

5. The wiring structure as claimed in claim 1, wherein the diffusion barrier layer pattern includes at least one selected from a silicon nitride, a tantalum oxide, a titanium oxide, a tantalum nitride, and a titanium nitride.

6. The wiring structure as claimed in claim 1, wherein the first and second insulating interlayers include at least selected from a borosilicate glass, a borophosphosilicate glass, an undoped silicate glass, a spin on glass, a flowable oxide, a tetraethyl orthosilicate, a plasma enhanced tetraethyl orthosilicate, a high density plasma oxide, and a high temperature oxide.

7. The wiring structure as claimed in claim 1, further comprising
a dummy plug on the second insulating interlayer, the dummy plug extending through the diffusion barrier layer pattern; and
a dummy wiring on the dummy plug.

8. The wiring structure as claimed in claim 7, wherein the dummy wiring is electrically isolated from the second wiring.

9.-15. (canceled)

16. A wiring structure, comprising:
a first contact structure on a substrate, the first contact structure including a first contact plug, a first wiring, a second contact plug, and a second wiring that are sequentially stacked on the substrate to be electrically connected to each other, and the first wiring extending through an insulating interlayer; and
a diffusion barrier layer pattern between the first wiring and the second wiring, the diffusion barrier layer pattern covering the first wiring and including a gap exposing a portion of the insulating interlayer.

17. The wiring structure as claimed in claim 16, wherein the second wiring overlaps the first wiring and the gap in the diffusion barrier layer pattern.

18. The wiring structure as claimed in claim 16, further comprising a second contact structure overlapping the gap in the diffusion barrier layer pattern, the second contact structure including a dummy plug and a dummy wiring.

19. The wiring structure as claimed in claim 18, wherein the dummy plug extends through the gap to be in contact with the insulating interlayer.

20. The wiring structure as claimed in claim 18, wherein the dummy plug and the dummy wiring are electrically isolated from the first contact plug, the second contact plug, the first wiring, and the second wiring.
